(19) United States
(12) Patent Application Publication
(10) Pub. No.: US 2008/0258223 A1
(43) Pub. Date: Oct. 23, 2008

(54) ESD PROTECTION DEVICE

(75) Inventor: Jen-Chou Tseng, Hsinchu (TW)

Correspondence Address: J C PATENTS, INC., 4 VENTURE, SUITE 250, IRVINE, CA, 92618, US

(73) Assignee: WINBOND ELECTRONICS CORP., Hsinchu (TW)

(21) Appl. No.: 11/775,614

(22) Filed: Jul. 10, 2007

(30) Foreign Application Priority Data
Apr. 18, 2007 (TW) 96113625

(51) Int. Cl. H01L 23/62

(52) U.S. Cl. 257/355; 257/E27.001

(57) ABSTRACT

An ESD protection device is provided. The ESD protection device of the present invention includes a semiconductor substrate/well, a first doped region, a second doped region and a third doped region. The first doped region doped with a first dopant is disposed in the semiconductor substrate/well. The second doped region doped with a second dopant is disposed in the semiconductor substrate/well, wherein a predetermined distance is maintained between the second doped region and the first doped region. The third doped region doped with the second dopant is disposed in the first doped region. The ESD protection device of the present invention is adapted for solving the reverse recovery problem of the conventional diode during the bipolar type ESD stressing.

### CROSS-REFERENCE TO RELATED APPLICATION

This application claims the priority benefit of Taiwan application serial no. 96113625, filed on Apr. 18, 2007. All disclosure of the Taiwan application is incorporated herein by reference.

### BACKGROUND OF THE INVENTION

1. Field of the Invention

The present invention relates to an ESD protection technique. More particularly, the present invention relates to a diode structure for ESD protection circuits.

2. Description of Related Art

During the manufacturing process of integrated circuits (ICs) or during the packaging process of chips, the electrostatic discharge (refers to ESD hereinafter) event is usually a main reason causing the ICs damage. For example, the human body walking on a carpet in an environment of a relatively high humidity may have a human-body model (HBM) ESD level of about several hundred to several thousand volts, and in an environment of a relatively low humidity, may have a HBM ESD level over about 10 thousand volts. Further, a packaging machine or a testing machine of the ICs may have a machine model (MM) ESD level of about several hundred volts to several thousand volts due to the influence of weather or humidity. In addition, because massive electric charges are stored in the substrate of semiconductor, so a charged device model (CDM) ESD level formed by the ICs releasing of the stored electric charges.

When these above cited charged bodies/devices touch the chips, the HBM/MM/CDM ESD level will discharge to the chips, which may cause the ICs within the chips damage. Therefore, for protecting the ICs within the chips, many kinds of ESD protection means have been studied, among which a commonly means is an on-chip hardware ESD protection circuits disposed between the internal circuit thereof and its corresponding pad to achieve protecting the ICs within the chips.

FIG. 1 is a circuit diagram of a conventional ESD protection circuit. The ESD protection circuit includes a plurality of diodes and a power clamping circuit. Since the diodes are a commonly used component in such ESD protection circuits, thus the characteristic of the diodes have a great influence in such ESD protection circuits. FIG. 2A and FIG. 2B are schematic diagrams respectively illustrating a reverse recovery current and a reverse recovery voltage of a conventional diode. Referring to FIGS. 2A and 2B, when the diode changes from a forward bias to a reversed bias, the minority carriers within the diode will cause an overshoot phenomenon of the voltage and the current. FIG. 3A and FIG. 3B are respectively a layout diagram and a cross-sectional view of a conventional diode. Referring to FIGS. 3A and 3B, when such diode is under a reversed bias, the minority carriers (i.e. holes) cannot pass through due to a energy band barrier between the N-well and the N+ doped region. FIG. 4 is a withstand voltage testing result of MM ESD level according to the diodes shown in FIGS. 3A and 3B. As can be seen from FIG. 4 that regardless whether it is a high voltage diode or a low voltage diode, its withstand voltage is about between −50˜100V due to the reverse recovery feature of such diode.

### SUMMARY OF THE INVENTION

The present invention is directed to an ESD protection device to solve the above-mentioned problem caused by the reverse recovery of the conventional diode.

The present invention is directed to an ESD protection device for improving the withstand voltage of the ESD protection circuit.

The present invention provides an ESD protection device includes a semiconductor substrate, a first doped region, a second doped region and a third doped region. The first doped region doped with a first dopant is disposed in the semiconductor substrate. The second doped region doped with a second dopant is disposed in the semiconductor substrate, wherein a predetermined distance is maintained between the second doped region and the first doped region. The third doped region doped with the second dopant is disposed in the first doped region.

In one of the embodiment of the present invention, the ESD protection device further includes a first well doped with a dopant different from that of the semiconductor substrate, wherein the first well is an N-well. Therefore, the first dopant is N+, and the second dopant is P+. Moreover, if the semiconductor substrate is a P type substrate, or the first well is a P-well, the first dopant is P+ and the second dopant is N+. Furthermore, the first doped region surrounds the second doped region.

In one of the embodiment of the present invention, the ESD protection device further includes a fourth doped region doped with the second dopant is disposed in the first well, wherein above-mentioned predetermined distance is maintained between the fourth doped region and the first doped region. The first doped region surrounds the second and the fourth doped regions, and the first and the third doped regions are disposed between the fourth doped region and the second doped region. As such, the first, the second, the third and the fourth doped regions comprise a finger-shaped structure profile.

Since the third doped region is disposed in the first doped region, and is doped with the second dopant, so as to the difference of energy bands in the semiconductor can be adjusted, and may solve the problem caused by the reverse recovery of the conventional diode, further the withstand voltage of the ESD protection circuit can be improved for protecting the ICs within the chips.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a circuit diagram of a conventional ESD protection circuit.

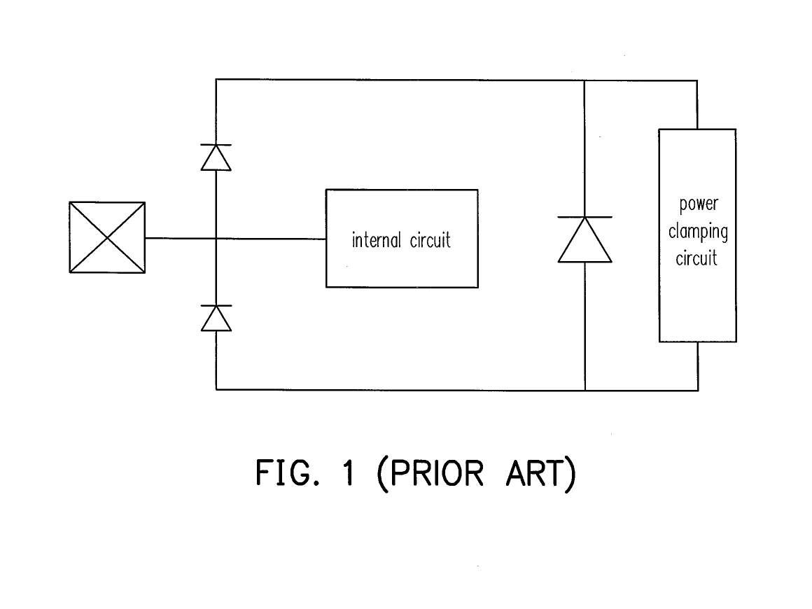

FIG. 2A and FIG. 2B are schematic diagrams respectively illustrating a reverse recovery current and a reverse recovery voltage of a conventional diode.

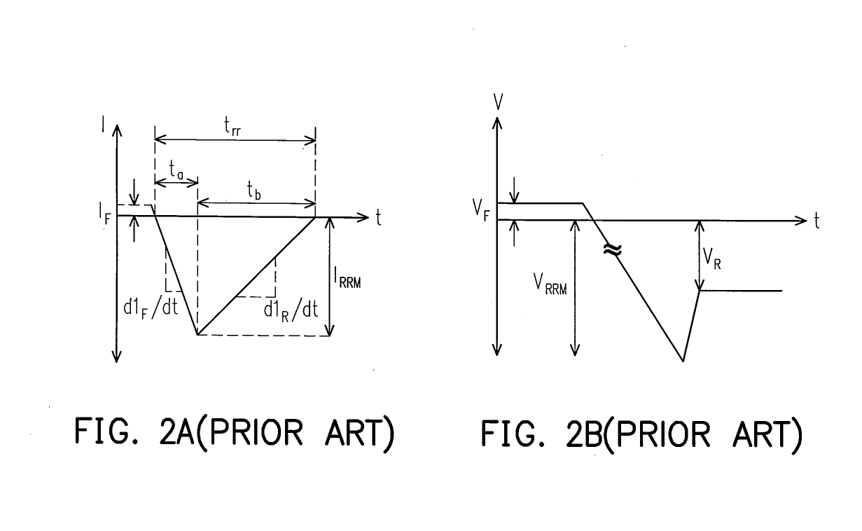

FIG. 3A and FIG. 3B are respectively a layout diagram and a cross-sectional view of a conventional diode.

FIG. 4 is a withstand voltage testing result of MM ESD level according to the diodes shown in FIGS. 3A and 3B.

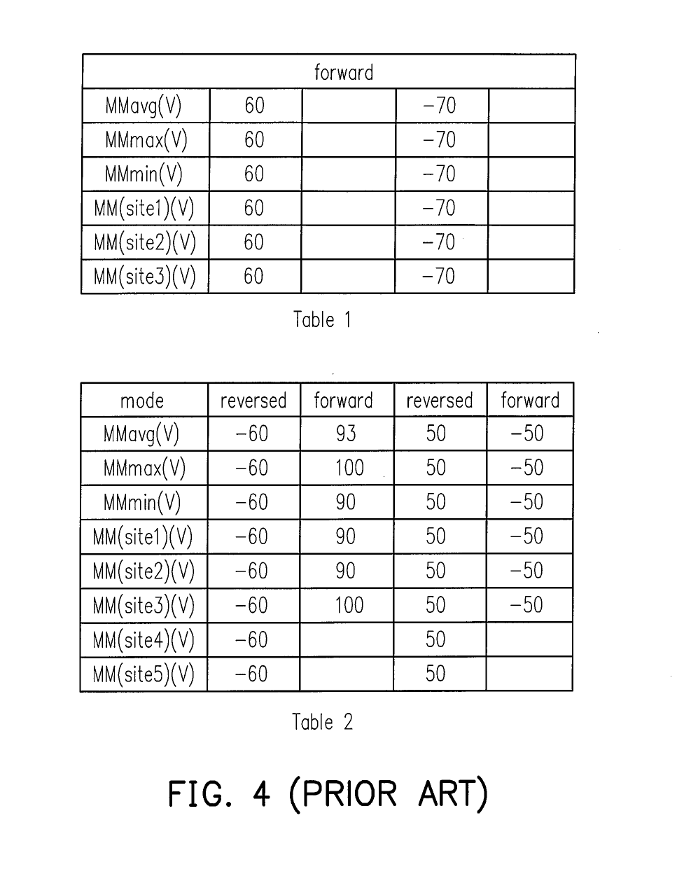

FIGS. 5A and 5B are respectively a layout structure diagram and a cross-sectional view of an ESD protection device according to an embodiment of the present invention.

FIGS. 6A and 6B are respectively a layout structure diagram and a cross-sectional view of another ESD protection device according to an embodiment of the present invention.

FIGS. 7A and 7B are respectively a layout structure diagram and a cross-sectional view of another ESD protection device according to an embodiment of the present invention.

FIG. 8 is a withstand voltage testing result of the ESD protection device shown in FIGS. 5A and 5B.

### DESCRIPTION OF EMBODIMENTS

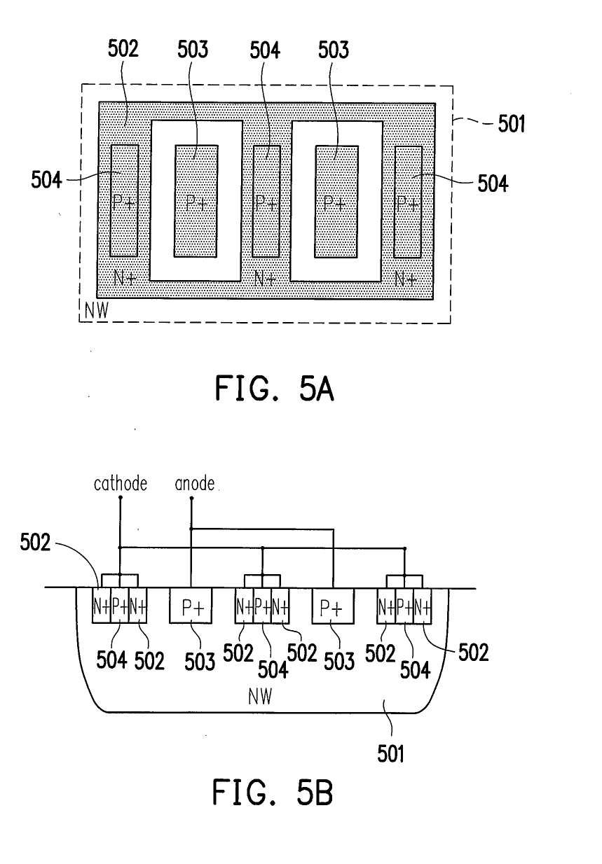

FIGS. 5A and 5B are respectively a layout structure diagram and a cross-sectional view of an ESD protection device according to an embodiment of the present invention. Referring to FIG. 5A, the layout structure diagram shown in FIG. 5A includes a N-well 501 disposed on the P-type semiconductor substrate, an N+ doped region 502, a plurality of P+ doped regions 503 and 504, wherein the N+ doped region 502 is disposed in the N-well 501. The P+ doped regions 503 are disposed in the N-well 501 and surrounded by the N+ doped region 502. The P+ doped regions 503 are respectively disposed in the N+ doped region 502. The aforementioned N+ and P+ doped regions 502˜504 comprise a finger-shaped structure profile.

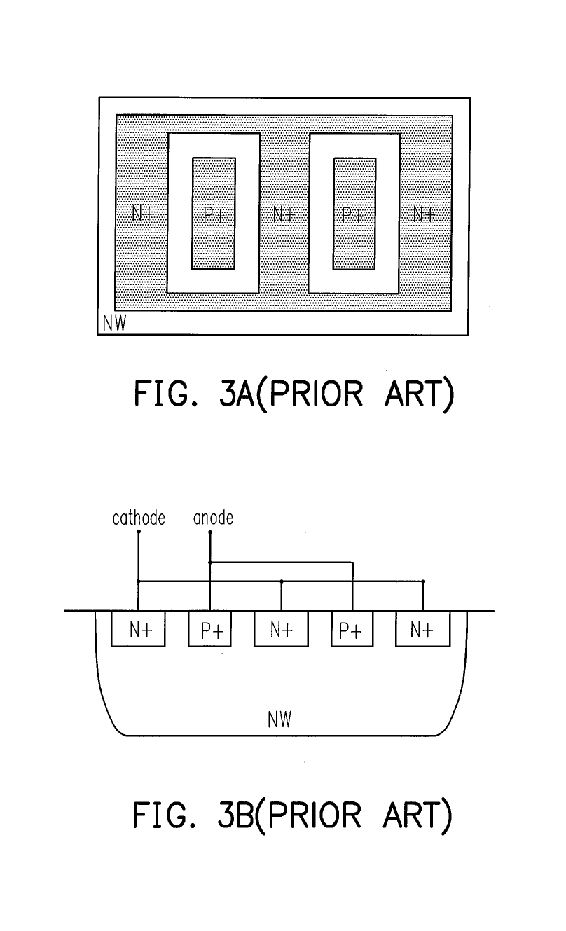

Referring to FIG. 5B, a anode of the ESD protection device in the present embodiment is composed of the P+ doped regions 503, and a cathode of the ESD protection device is composed of a well pick up area formed by the N+ doped region 502 and P+ doped regions 504 within the well pick up area. Since the ESD protection device of the present embodiment has a plurality of P+ doped regions 504 and the structure thereof is totally different compared to that of a conventional diode shown in FIGS. 3A and 3B, the minority carriers (holes) can conducted to the cathode through the P+ doped region 504 within the well pick up area. Therefore, the energy band barrier that the minority carriers should pass through when moving from the anode to the cathode is reduced greatly in the ESD protection device.

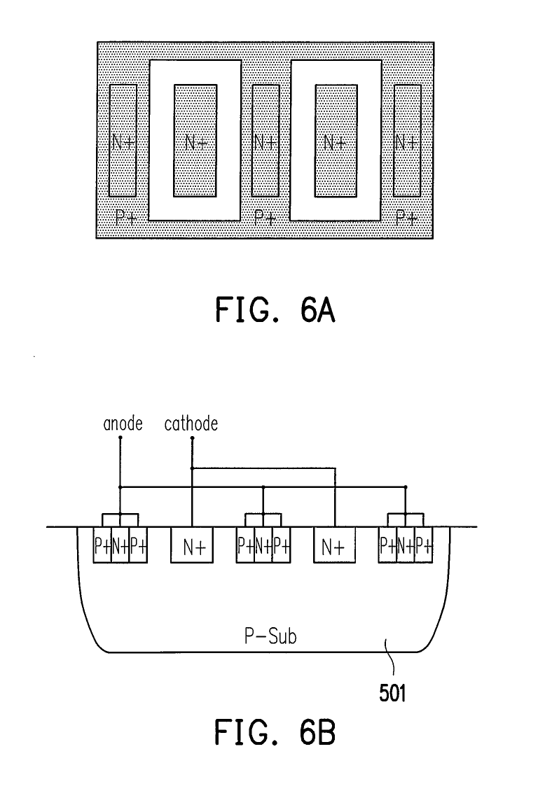

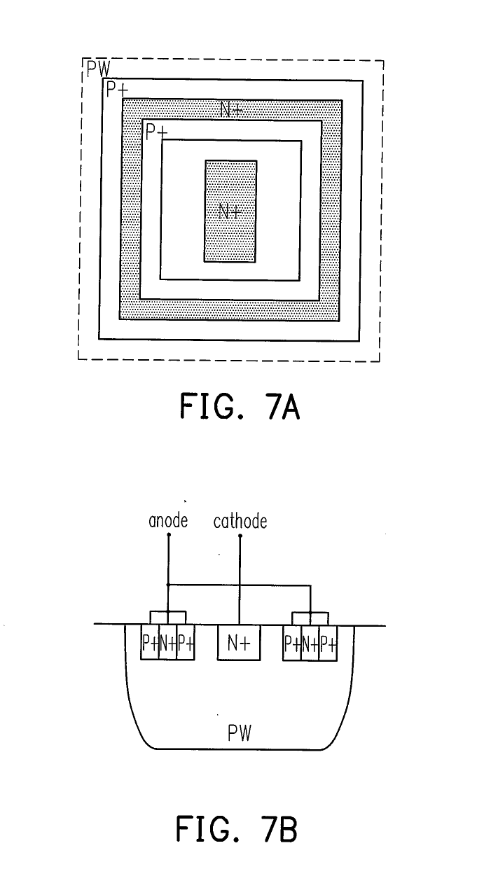

Though the present invention provides such ESD protection device and its cross-sectional view diagram for a reference to those having ordinary skill in the art, it should be noted that the aforementioned layout structure will have the same function if N+ and P+ doped regions are exchanged as shown in FIGS. 6A and 6B. Moreover, the layout structure still has the same function if being modified as shown in FIGS. 7A and 7B. Thus, the present invention is not limited to the aforementioned embodiments.

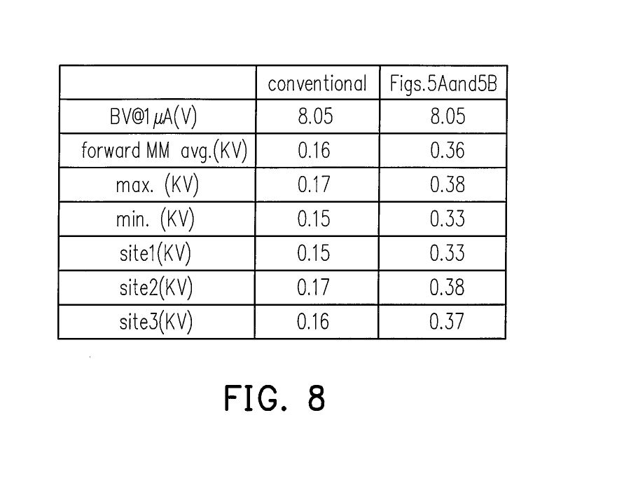

FIG. 8 shows a withstand voltage testing result of the present ESD protection device shown in FIGS. 5A and 5B. Referring to FIG. 8, under the same condition as that of a conventional diode shown in FIGS. 3A and 3B, the withstand voltage of the ESD protection device shown in FIGS. 5A and 5B is nearly twice the bigger than that of the conventional diode shown in FIGS. 3A and 3B.

In summary, since the third doped region is disposed in the first doped region, and is doped with the second dopant, so as to the difference of energy bands in the semiconductor can be adjusted, further the problem caused by the reverse recovery of the conventional diode can be resolved, and the withstand voltage of the ESD protection circuit is also improved for protecting the ICs within the chips.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An ESD protection device, comprising:
a semiconductor substrate;
a first doped region doped with a first dopant, disposed in the semiconductor substrate;
a second doped region doped with a second dopant, disposed in the semiconductor substrate; and
a third doped region doped with the second dopant, disposed in the first doped region, wherein a predetermined distance is maintained between the second doped region and the first doped region.

2. The ESD protection device as claimed in claim 1 further comprising a first well doped with a dopant different from that of the semiconductor substrate.

3. The ESD protection device as claimed in claim 2, wherein the first well comprises an N-well.

4. The ESD protection device as claimed in claim 3, wherein the first dopant comprises N+.

5. The ESD protection device as claimed in claim 3, wherein the second dopant comprises P+.

6. The ESD protection device as claimed in claim 1, wherein the first well comprises a P-well.

7. The ESD protection device as claimed in claim 1, wherein the semiconductor substrate comprises a P-type substrate, and the first dopant comprises P+.

8. The ESD protection device as claimed in claim 1, wherein the semiconductor substrate comprises a P-type substrate, and the second dopant comprises N+.

9. The ESD protection device as claimed in claim 1, wherein the first doped region surrounds the second doped region.

10. The ESD protection device as claimed in claim 1 further comprising a fourth doped region doped with the second dopant disposed in the first well, wherein a predetermined distance is maintained between the fourth doped region and the first doped region, the first doped region surrounds the second and the fourth doped regions, and the first and the third doped region are disposed between the fourth doped region and the second doped region.

11. The ESD protection device as claimed in claim 10, wherein the first, the second, the third and the fourth doped regions comprise finger-shaped structure profile.
